(19) United States
(12) Patent Application Publication
(10) Pub. No.: US 2012/0086463 A1
(43) Pub. Date: Apr. 12, 2012

(54) Metamaterial Particles for Near-Field Sensing Applications

(76) Inventors: Muhammed S. Boybay, Kitchener (CA); Omar M. Ramahi, Waterloo (CA)

(21) Appl. No.: 12/902,584

(22) Filed: Oct. 12, 2010

(51) Int. Cl. G01R 27/28; G01R 1/06

(52) U.S. Cl. 324/612; 324/149

(57) ABSTRACT

A method and structure for designing near-field probes with high sensitivity used in detecting a wide variety of materials and objects such as biological anomalies in tissues, cracks on metallic surfaces, location of buried objects, or composition of material such as permittivity and permeability . . . etc., is disclosed. The present invention includes using single or multiple metamaterial unit cells or metamaterial particles as near-field sensors. Metamaterial unit cells are defined as the building blocks used for fabricating metamaterials that provide electrical or magnetic properties not found in naturally occurring media. Metamaterial unit cells or particles include split-ring resonators, complementary split-ring resonators, or a variety of other electrically-small resonators made of conducting wires or conducting flat surfaces. Metamaterial unit cells are excited by appropriate excitations such as small loops, microstriplines, etc. depending on the electromagnetic properties of the metamaterial unit cell. Once the metamaterial unit cell is excited, the reflection and transmission coefficients from the excitation mechanism can be measured.

### CROSS-REFERENCE TO RELATED APPLICATIONS

Not Applicable

### STATEMENT REGARDING FEDERALLY SPONSORED RESEARCH OR DEVELOPMENT

Not Applicable

### FIELD OF THE INVENTION

The present invention relates generally to devices which typically employ radio signals, microwaves or signals in the optical frequency regime, and in particular to devices typically referred to as near-field probes that use transmitted and reflected signals to characterize the composition of material or to detect abnormalities or defects in materials or surfaces such as cracks in metallic surfaces, biological anomalies in tissues, changes in physical parameters of media such as variation in surface resistivity, or detection of hidden subsurface objects such as landmines, delamination in circuits, subsurface voids, or lamination abnormalities.

### BACKGROUND OF THE INVENTION

Sensing or characterization of electromagnetic properties of materials has important applications. Characterization of materials is needed for material classifications and selection for specific applications. In addition, other physical properties such as moisture, temperature, water content, concentration of chemical components, etc. have effects on the electromagnetic properties of materials. Therefore sensing the electromagnetic properties of materials is also being used in the food industries, biomedical applications, military applications, etc. Detecting buried objects is another application of sensing electromagnetic properties of materials. Since each material has unique material properties, buried objects can be detected by sensing the electromagnetic properties.

Methods of characterization using electromagnetic waves can be classified in two categories. The first class uses propagating waves for the characterization such as methods based on radars, Gaussian beams, etc. In methods where the propagating waves in free space are used, a wave is generated using an antenna or a radiator. In such methods, the reflection and transmission from the material under test is recorded from which the material properties can be calculated. In these methods, costly and bulky equipments are needed including antennas, lenses, etc. In addition, since the propagating waves cannot be focused into spot sizes smaller than the wavelength at the operation frequency, large samples of material under test are needed for the characterization. This limitation also puts constraints on the resolution of systems that are based on propagating waves. The resolution of such systems cannot be smaller than half of a wavelength. Therefore electrically small targets or material properties localized to regions smaller than half of a wavelength cannot be detected. The term electrically small refers to sizes smaller than the wavelength at the operation frequency.

In addition to the methods where propagating waves in free space are used, there are methods that use propagating waves in transmission lines or waveguiding structures. In this method the sample under test is employed as a filling material for the transmission lines or waveguiding structure. For example, a slab of material can be inserted into a waveguide or the insulating material of a coaxial line can be replaced by the sample under test. The transmission and reflection form the sample-filled region gives the information needed for extraction of material properties. The method needs extensive sample preparation and does not give information about irregularities in the material. Therefore this method cannot be used for detecting buried objects or cannot be used for applications where local material properties are needed.

The second class of characterization methods uses evanescent fields for the characterization and are mainly named as near-field probes. In these methods, a scanning near-field probe or sensor is used to locally determine the material properties. Fields are localized by using a small tip, where evanescent fields are generated. Since evanescent fields are not limited by the diffraction limit, the spot size of the localized field can be much smaller than the wavelength. The interaction between evanescent fields and the material under test is used for the characterization. In this method the sample size can be smaller, and a single probe is needed for the entire measurement where on the other hand more than one antenna is needed in the case of systems based on propagating waves. The method can detect electrically small objects and sense the material properties localized to regions smaller than the wavelength. These features make the use of low frequency electromagnetic waves possible which has advantages such as lower cost and better penetration to lossy media. Designing near-field probes are challenging since the resolution, or in other words the spot size of the field generated by the probe, and the sensitivity of the probe usually cannot be improved simultaneously.

In addition to detecting the presence of an object within a homogeneous medium, near-field probes are also used to determine the position of a target within a host medium, specifically, the depth of the target.

Near-field probes are operated at one or more frequencies. The characterization or detection takes place by processing the reflected signal coming out of the probe. If the distance between the probe and the target increases, or the distance between the probe and the interrogated material increases, then the sensitivity drops. Near-field probes can be comprised of resonating or non-resonating electromagnetic devices. Irrespective of the mode of operation (resonance, or non-resonance), the near-field probe reacts to change in the stored magnetic and electric energy within the space including and surrounding the probe.

### SUMMARY OF THE INVENTION

The present invention describes a new method for designing new near-field probes with high sensitivity by using unit cells of metamaterials. These unit cells are henceforth referred to as particles. Metamaterials are defined as artificially engineered materials designed for a specific permittivity and/or permeability response. A unit cell which is usually electrically small and resonating is designed and the metamaterial is obtained by periodically filling the space with a periodic or aperiodic ensemble of these unit cells. The present invention is based on the use of a single unit cell or particle of a metamaterial. The new method has advantages of confining near-fields to an electrically small volume and increasing the near-field strength. As a result the method has the capabilities of producing subwavelength images with very high sensitivity. Furthermore, the new method has the advantage of increasing the sensitivity when the near-field probe is used for material characterization and sub-surface detection. Reference is made to Smith, D., Schultz, S., Kroll, N., Shelby, R. A., Left handed composite media, U.S. Pat. No. 6,791,432, Sep. 14, 2004, as an example of metamaterial design and specifications.

Conventional near-field probes are based on confining electromagnetic fields in an electrically small volume by producing high spatial evanescent field components. Usually a small tip is connected to a resonator to leak some of the energy stored by the resonator to out of the resonator. The following references describe sample near-field probe systems.
Anlage, S. M., Steinhauer, D. E., Vlahacos, C. P. and Wellstood, F. C. Quantitative imaging of dielectric permittivity and tunability. U.S. Pat. No. 6,809,533, Oct. 26, 2004.
Xiang, X.-D. and Gao, C., Scanning evanescent electro-magnetic microscope. U.S. Pat. No. 6,173,604, Jan. 16, 2001.
Ookubo, N. Scanning microwave microscope capable of realizing high resolution and microwave resonator. U.S. Pat. No. 6,614,227, Sep. 2, 2003.
Tabib-Azar, M., Shoemaker, N. S. and Harris, S. “Non-destructive characterization of materials by evanescent microwaves,” Meas. Sci. Technol., Vol. 4, May, 1993, pp. 583-590.
Tabib-Azar, M., Katz, J. L. and LeClair, S. R. “Evanescent microwaves: A novel super-resolution noncontact nondestructive imaging technique for biological applications,” IEEE Trans. On Instr. And Meas., Vol: 48, December, 1999, pp. 1111-1116.

The resonance frequency of the resonator changes when the energy of the leaked field interacts with a sample. Such change is dependent on the position, shape, size or material properties of the sample. As a result the field energy that interacts with the sample is a small portion of the total field energy. In such a structure, as the size of the probe is made smaller, a better field confinement is achieved and as a result the resolution increases. On the other hand, when the probe decreases in size, the leaked energy becomes smaller, resulting in reduced sensitivity. Therefore increasing both the sensitivity and the resolution of near-field probes is challenging task.

In the new invention, instead of leaking some portion of the resonating field energy from the resonator by an electrically small tip, an electrically-small resonating device is used. The resonating device is a metamaterial unit cell or metamaterial particle. The metamaterial particle resonating device is characteristically different from resonators that are defined by closed metallic boundaries such as rectangular or cylindrical cavities. Such cavities have dimensions that are comparable to the wavelength at which the resonators operate, whereas the metamaterial particle device has a dimension much smaller than the wavelength at the frequency of operation. Therefore the target can interact with a higher portion of the total resonating field energy. The resonating metamaterial particle device produces a field confined to an electrically small volume while simultaneously generates high field intensity. Consequently, increasing both the sensitivity and the resolution of near-field probes are achieved simultaneously.

The metamaterial unit cells are electrically small resonators. Electrically small resonators refer to the resonators where within the structure the time factor of propagation is negligible. Therefore these structures are based on generating capacitances and inductances by electrically small elements. The resonators can be based on magnetic field excitation such as in the case of split-ring resonators (SRRs) or can be based on electric field excitation such as in the case of capacitive loaded strips (CLSs). Similar to these structures, broadside coupled split-ring resonators, double split-ring SRRs, spirals and complementary split-ring resonators are some examples of metamaterial unit cells.

Based on these definitions, a near-field probe employing a metamaterial unit cells can be excited by appropriate transmission or waveguiding media such as transmission lines or circuits and the resonance frequency or the amplitude/phase of the reflection coefficient can be measured as an indication of properties, shape, size of other attributes of sample or material under study.

### BRIEF DESCRIPTION OF THE DRAWINGS

FIG. 1a is a view of an edge coupled split-ring resonator, an example for metamaterial unit cell.

FIG. 1b is a view of a side coupled split-ring resonator, an example for metamaterial unit cell.

FIG. 1c is a view of an edge coupled complementary split-ring resonator, an example for metamaterial unit cell.

FIG. 1d is a view of a spiral resonator, an example for metamaterial unit cell.

FIG. 1e is a view of a Fractal Hilbert2 curve resonator, an example for metamaterial unit cell.

FIG. 1f is a view of a double split-ring resonator, an example for metamaterial unit cell.

FIG. 2 is description of the edge coupled split-ring resonator presented as a sample near-field probe design.

FIG. 3 is the system used for excitation of edge coupled split-ring resonator sensor and the system for measuring reflection coefficient from the sensor.

FIG. 4 is a chart showing the variability of the resonance frequency of the edge coupled split-ring resonator as a function of standoff distance.

FIG. 5 is a chart showing the variability of the resonance frequency of the edge coupled split-ring resonator as a function of the relative permittivity of the space.

FIG. 6 is a chart showing the variability of the resonance frequency of the edge coupled split-ring resonator as a function of the relative permeability of the space

FIG. 7 is a chart showing the variability of the resonance frequency of the edge coupled split-ring resonator as a function of the relative loss tangent of the space

FIG. 8 is description of the edge coupled complementary split-ring resonator presented as a sample near-field probe design.

FIG. 9 is a view of microstripline structure used for the excitation of the edge coupled complementary split-ring resonator

FIG. 10 is the system used for excitation of edge coupled complementary split-ring resonator sensor and the system for measuring reflection coefficient from the sensor. The position of the sample material for sensing electrical properties is shown.

FIG. 11 is a chart showing magnitudes of the reflection and transmission coefficients of microstripline with edge coupled complementary split-ring resonator. The reflection and transmission coefficients are presented for sample materials with relative permittivities of 1 and 3.

FIG. 12 is a chart showing the variability of the minimum S₁₁, and S₂₁ frequencies as a function of permittivity of the sample material.

FIG. 13 is a chart showing phase of the reflection and transmission coefficients of microstripline with edge coupled complementary split-ring resonator. The reflection and transmission coefficients are presented for sample materials with relative permittivities of 1 and 3.

FIG. 14 is a chart showing the variability of the phase of S₁₁, and S₂₁ as a function of permittivity of the sample material.

### DETAILED DESCRIPTION OF THE INVENTION

The invention describes a new concept for designing near-field probes. The new probe is an electrically small resonator as the details are described in the following parts. The resonator is excited by an appropriate structure depending on the shape and resonance mechanism of the resonator. To excite the resonator and measure the reflection coefficient, the probe is connected to a device such as VNA or to a more compact phase detector circuit via a transmission line. When a target interacts with the evanescent fields generated by the probe, or when the material composition of the sample under test changes as the probe scans over the sample, the change is detected by recording the resonance frequency. For a more sensitive measurement, the change in the phase of the reflection coefficient at the resonance frequency is measured. The resonance frequency shift as a result of the change in material properties or the change in geometry is given by the perturbation theory. According to D. M. Pozar, Microwave Engineering, Wiley, Hoboken, N.J., 2005, the resonance frequency shift due to a change in the material properties is given by

$$\frac{Δ {f}_{r}}{{f}_{r}} = \frac{{\int }_{v}^{ } ( {ΔɛE}_{1} \cdot {E}_{0}^{*} + Δ μ {H}_{1} \cdot {H}_{0}^{*} ) d v}{{\int }_{v}^{ } ( ɛ {E}_{1} \cdot {E}_{0}^{*} + μ {H}_{1} \cdot {H}_{0}^{*} ) d v}$$

where Δfᵣ is the shift in the resonance frequency, fᵣ, Δ∈ and Δμ are the changes in the permittivity and permeability and v is the perturbed volume. E₀ and H₀ are the field distributions without the perturbation and E₁ and H₁ are the field distributions with the perturbation.

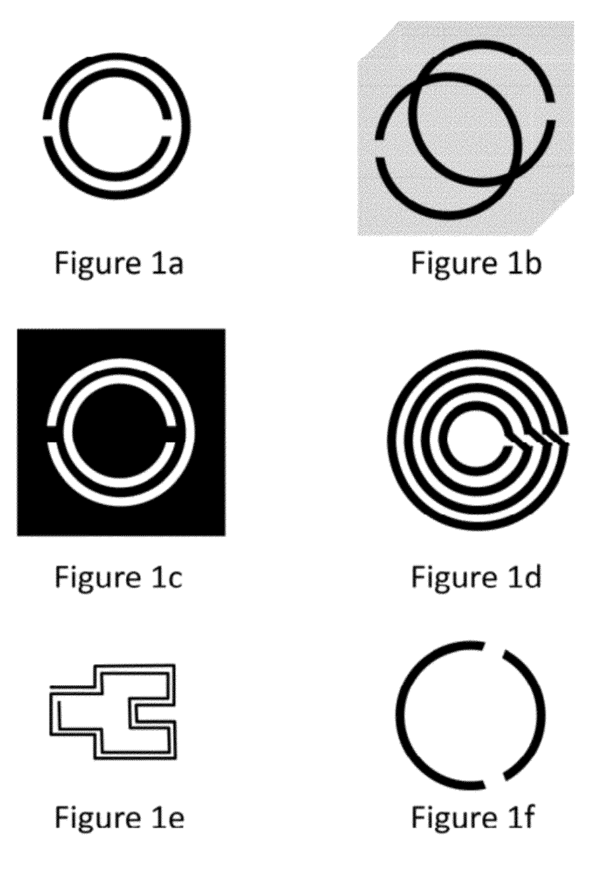

In FIG. 1, sample shapes for electrically small resonators are presented. Electrically small resonators are mostly used in periodic structures named as metamaterials, frequency selective surfaces or electromagnetic band gap structures. FIG. 1a and FIG. 1b are named edge coupled split-ring resonator and side coupled split-ring resonator, respectively and are both used in metamaterial designs to obtain magnetic response at microwave frequencies. These structures are composed of two conductive loops with gaps deposited on a dielectric substrate. The structure presented in FIG. 1c is a complementary split-ring resonator which is developed from an edge coupled split-ring resonator by invoking Babinets Principle, according to F. Falcone. T. Lopetegi, M. A. G. Laso, J. D. Baena. J. Bonache, M. Beruete, R. Marqués, F. Martín, M. Sorolla, Babinet Principle Applied to the Design of Metasurfaces and Metamaterials, Physical Review Letters, Vol. 93, November 2004, p. 197401. In the complementary split-ring resonators, the conductive regions in FIG. 1a are etched and the etched regions in FIG. 1a are conductive. The structure is used in metamaterial designs to obtain electrical response at microwave frequencies. There are also other resonating structures inspired from metamaterial designs such as a spiral resonator as shows in FIG. 1d and Hilbert curves resonators as shown in FIG. 1e. In addition to unit cells of metamaterials, unit cells of frequency selective surfaces are also electrically small resonators. FIG. 1f shows an asymmetric double split-ring which is a type of frequency selective surfaces.

Without loss of generality, two sensor geometries and excitation systems are described as two example. These are based on the Split-ring Resonator and the Complementary Split-ring Resonator. Other metamaterial sensors based on other geometries typically used to constitute metamaterials, such as Double Split-Ring Resonators, Double Split Square Resonators, Singly Split-ring Resonators, Two-Turn Circular or Rectangular Spiral Resonators, Hilbert Fractal Resonators, Modified Ring Resonators, Metasolenoid, Swiss Roll Resonators, amongst others, with appropriate excitation systems can also be designed based on this method.

Split-ring Resonator Sensor with Loop Excitation:

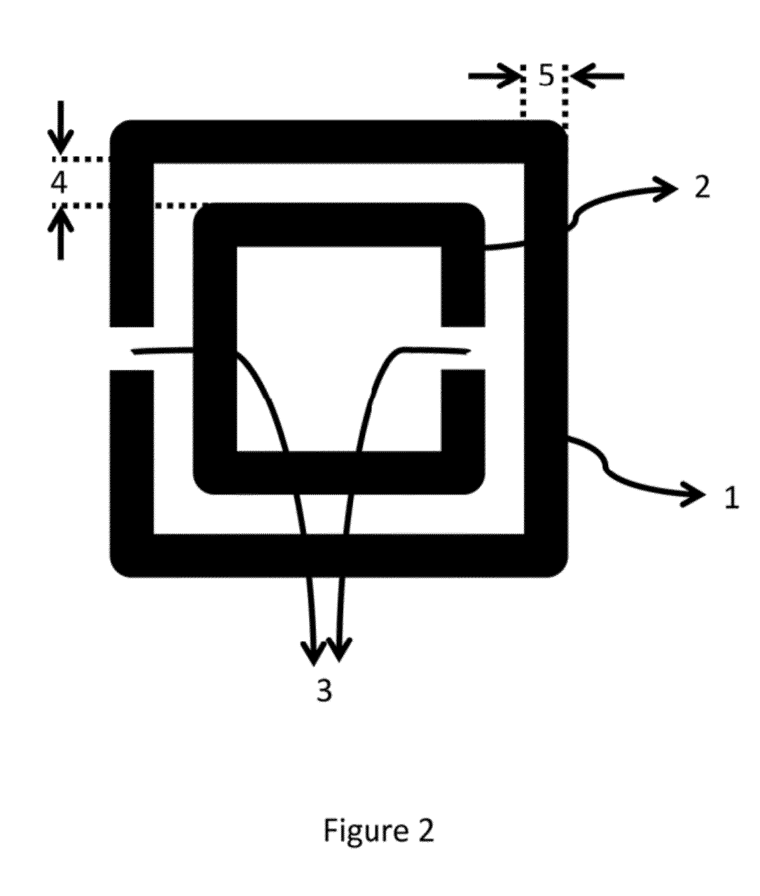

A near-field probe or sensor based on an edge coupled split-ring resonator (SRR) is described as shown in FIG. 2. In this example, the resonance frequency of the probe is 415.5 MHz when it is placed in free space. All the dimensions are described in terms of the free-space wavelength, λ, at the resonance frequency of 415.5 MHz. The structure is composed of two concentric rectangular loops 1 2. The size of the larger loop 1 is λ/16×λ/16 (1.8 in×1.8 in). Each loop has a gap 3 with a size of λ/282 (0.1 in). The separation between the loops 4 is λ/564 (0.05 in). The width of conductive strips 5 is λ/282 (0.1 in). The rings are etched on a substrate made of FR4 with a thickness of λ/940 (0.03 in). The conductive regions are made of copper with a thickness of 4.18e−5λ (1.18 mil). Other substrates of lower electric loss can be used.

The current circulating in the conductive rods generates a magnetic field passing through the loops, which makes the structure behave as a inductor. This current also experiences a capacitance which is mainly a result of the capacitance between the loops and the capacitance at the gaps. Based on the formulation presented in Pendry et al. in Magnetism from conductors and enhanced nonlinear phenomena, IEEE Trans. Microwave Theory and Techniques, vol. 47, no. 11, pp. 2075-2084, November 1999, the resonance frequency of such a structure can be calculated using the following equations

$${μ}_{eff} = 1 - \frac{\frac{{s}^{2}}{{a}^{2}}}{1 + i \frac{4 l σ}{ω s {μ}_{0}} - \frac{l}{{μ}_{0} {ω}^{2} {s}^{2} C}}$$

where c₀ is the speed of light in free space, a is the separation between two resonators in the same plane, s is the side length of the larger loop, C is the capacitance between unit length of two parallel sections of the metallic strips. Note that this formulation is derived for metamaterial designs and l corresponds to the separation between two consecutive resonators. Although in our system there is only one resonator, this formula presents an acceptable starting point for the design process. The final dimensions of the probe are determined either by numerical simulation tools, or physical experiments.

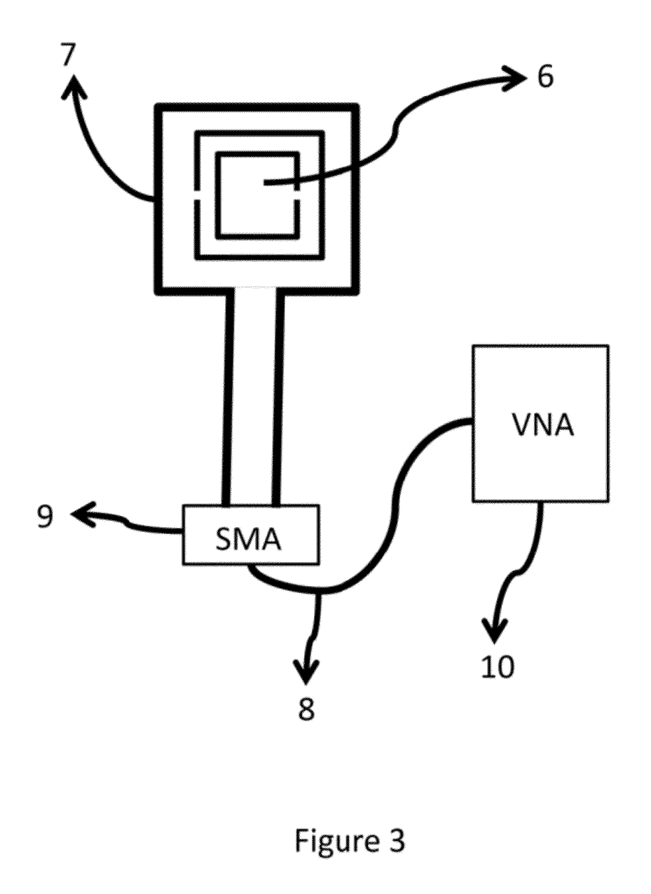

FIG. 3 describes the system for excitation and measurement of the resonating device that constitutes the near-field probe or sensor. The SRR 6 is excited by a rectangular loop 7, which is connected to a coaxial line 8 through an SMA connector 9. The measurement is conducted by a vector network analyzer 10. The loop generates a magnetic field passing through its center. Since the loop and the SRR are concentric, the magnetic field generated by the loop excites the SRR and the resonant behavior is observed by the reflection coefficient measurement using a vector network analyzer.

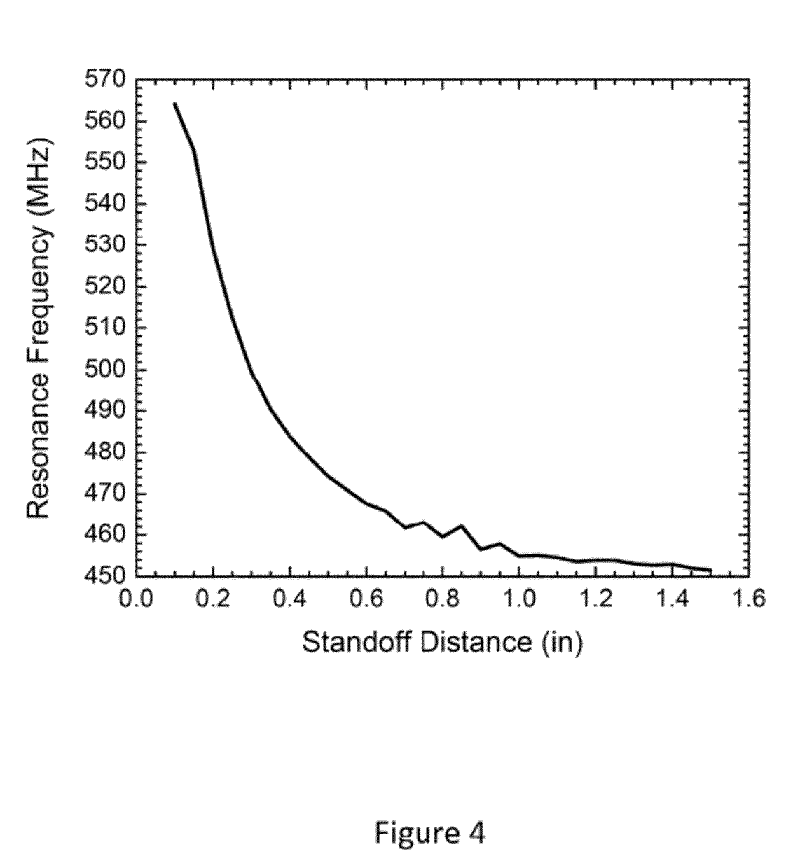

The behavior of the SRR is analyzed numerically for detection purposes. FIG. 4 shows the resonance frequency when there is a conductive plate next to the SRR. The resonance frequency as a function of the separation between the SRR and the conductive plate is plotted.

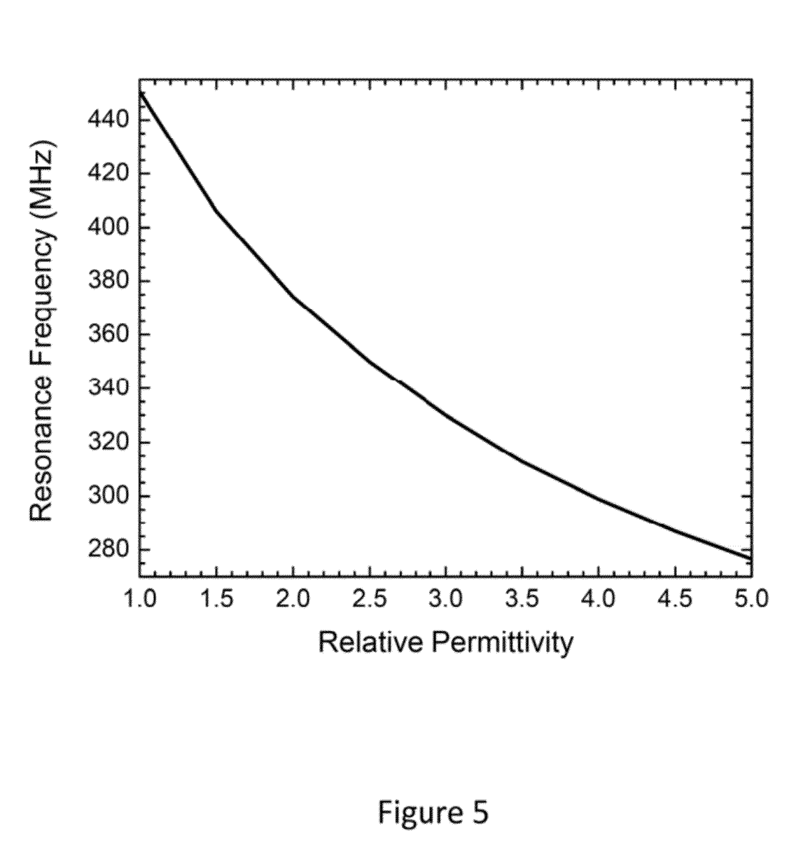

The behavior of the SRR is analyzed numerically for relative permittivity measurement purposes. FIG. 5 shows the resonance frequency as a function of the relative permittivity of the space. The material property of the substrate on which the SRR is printed is assumed to be unchanged.

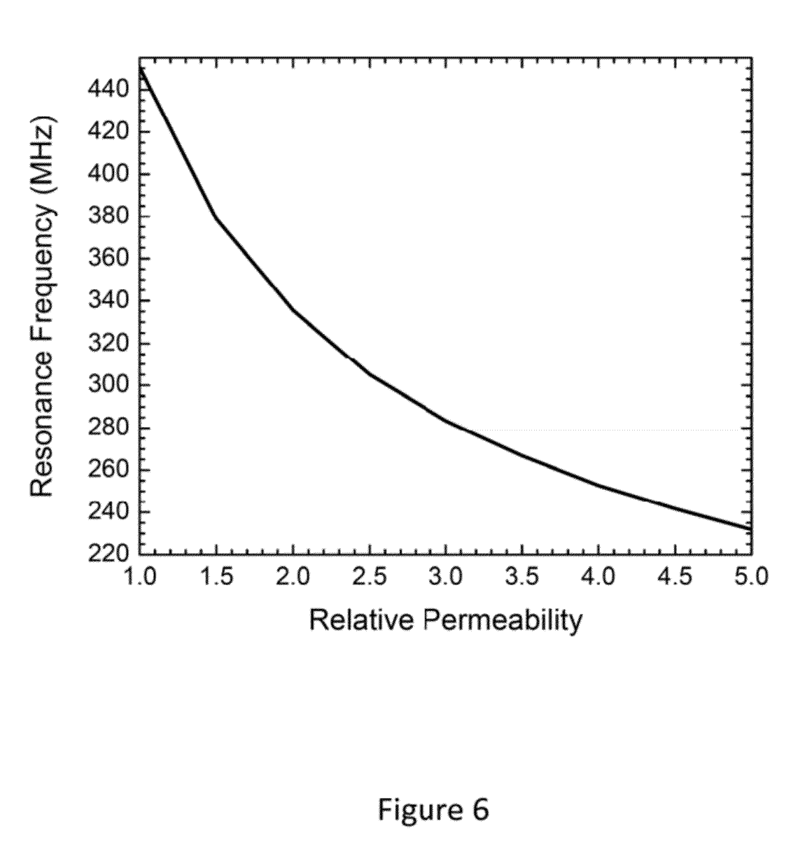

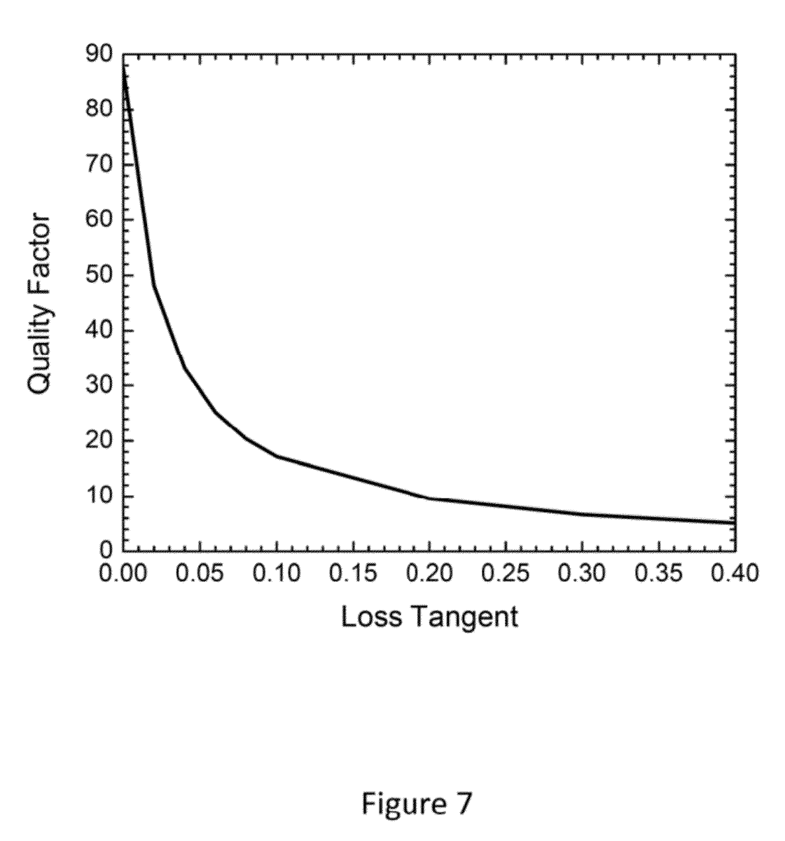

The behavior of the SRR is analyzed numerically for relative permeability measurement purposes. FIG. 6 shows the resonance frequency as a function of the relative permeability of the space. The material property of the substrate on which the SRR is printed is assumed to be unchanged.

The behavior of the SRR is analyzed numerically for loss tangent measurement purposes. FIG. 6 shows the quality factor as a function of the loss tangent of the space. The material property of the substrate on which the SRR is printed is assumed to be unchanged.

Complementary Split-ring Resonator Sensor with Microstrip Excitation:

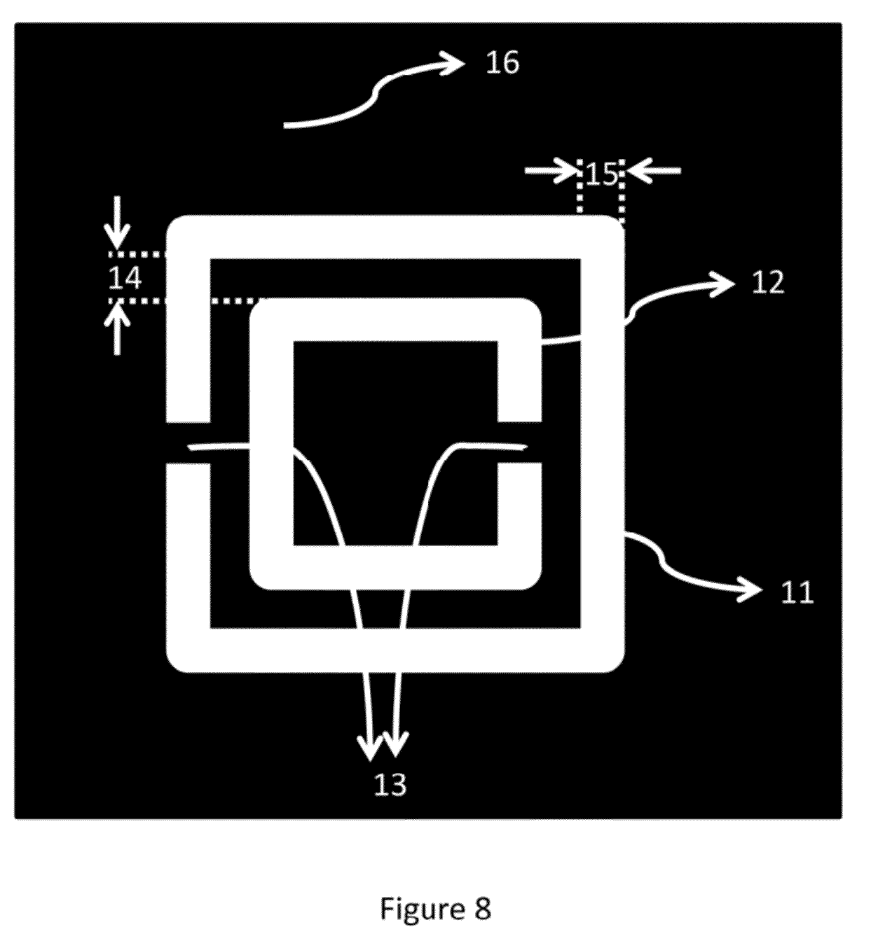

A sensor based on an edge coupled complementary split-ring resonator (CSRR) is described as shown in FIG. 8. The resonance frequency of the CSRR is 1.56 GHz when it is placed in free space. All the dimensions are described in terms of the free-space wavelength, λ, at the resonance frequency of 1.56 GHz. Two concentric rectangular loops 11 12 are etched out from a conductive plane 16 in order to generate CSRR. The size of the larger loop 11 is λ/16×λ/16 (0.47 in×0.47 in). Each loop has a gap 13 with a size of λ/961 (0.008 in). The separation between the loops 14 is λ/1920 (0.004 in). The width of etched out traces 15 is λ/1920 (0.004 in). The rings are etched on a substrate made of Rogers RO3003 with a thickness of λ/252 (0.03 in). The conductive regions are made of copper with a thickness of λ/6400 (1.18 mil).

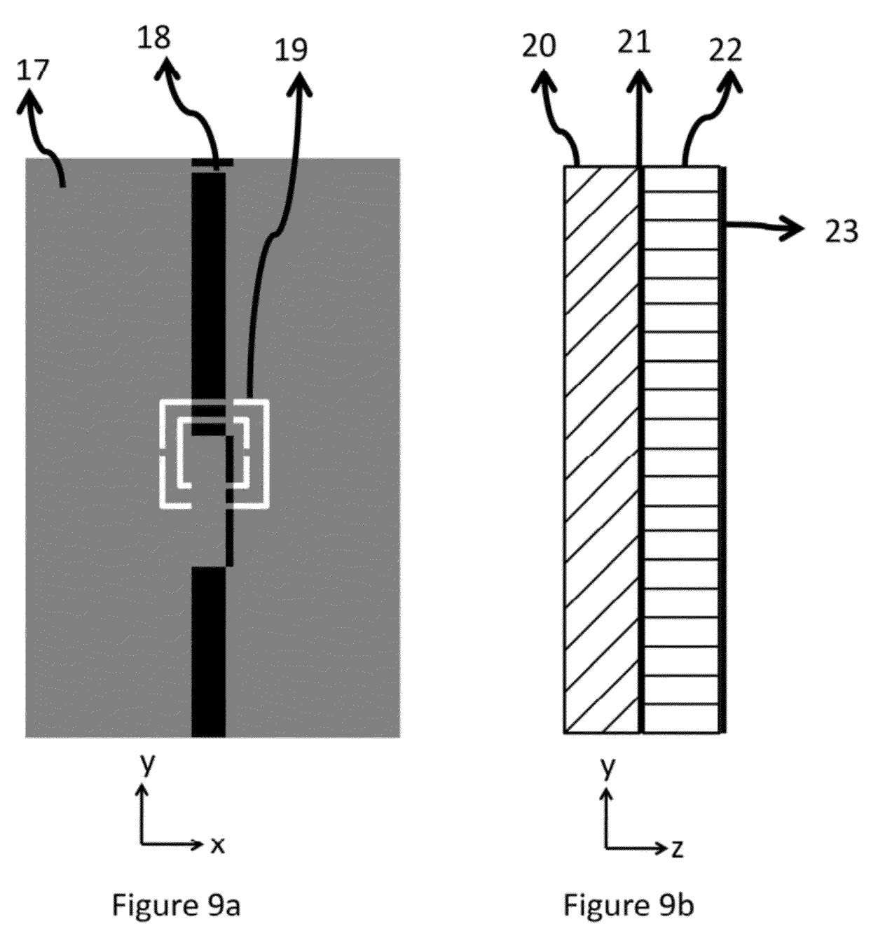

FIG. 9-a shows the excitation structure for the CSRR sensor. In order to excite a CSRR structure, an electric field perpendicular to the CSRR plane is needed. Therefore when a CSRR 19 is etched out on the ground plane 17 of a microstripline 18 the CSRR can be excited. The resulting structure is a stopband filter. Therefore, as the sample is placed at the bottom of the board, as shown in FIG. 9-b, the resonance frequency of the CSRR changes, resulting in a shift in the filtering characteristics. For the examples presented in this document, in order to have a 50Ω line, the width of the microstripline is chosen to be λ/104 (0.07 in). The microstripline is assumed to be λ/1.92 (3.94 in) long and the width of the ground plane is λ/3.84 (1.97 in).

FIG. 9-b shows the side view of the microstripline with CSRR. The ground plane 21 on which the CSRR is etched is separated from the microstripline 23 by a substrate 22. The sample under test 20 is placed next to the ground plane.

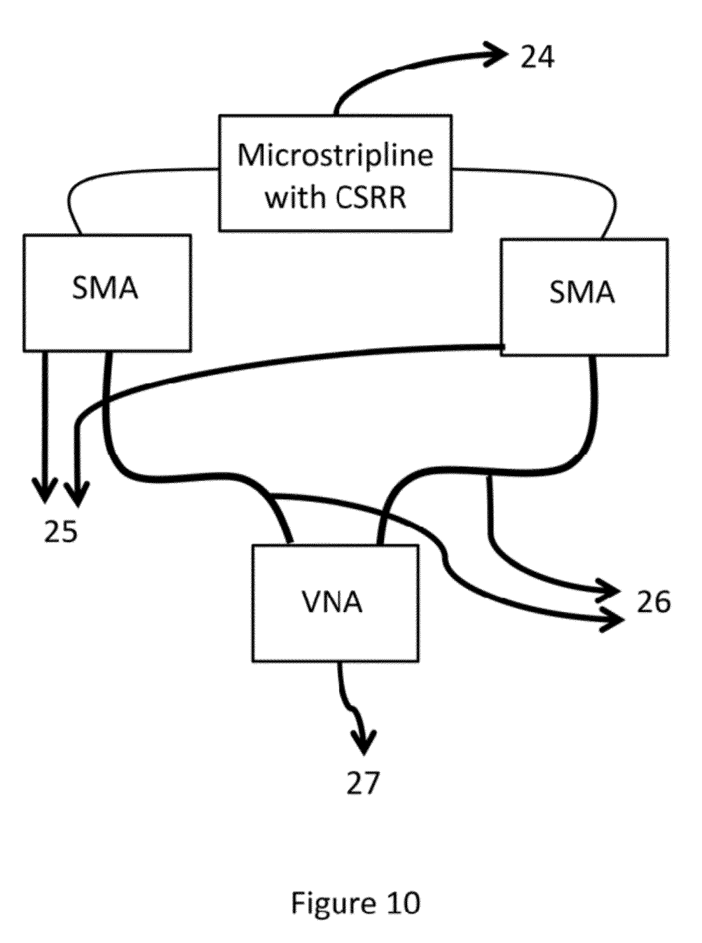

FIG. 10 shows the schematic of the system used for the excitation of the sensor and the measurement of the reflection and transmission coefficients. The microstripline 24 is connected to coaxial lines 26 with SMA connectors 25. A VNA 27 can be used for measuring the reflection and transmission coefficient.

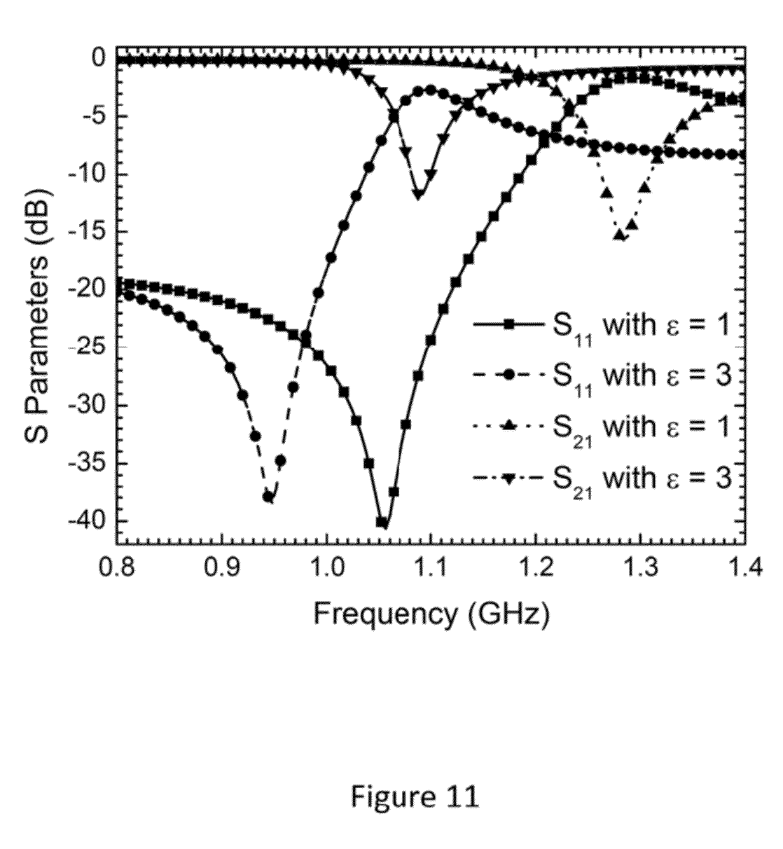

FIG. 11 shows the magnitudes of the reflection and transmission coefficients as a function of frequency. The transmission coefficient experiences a minimum value at a frequency of 1.284 GHz when the relative permittivity of the sample under test is equal to I. In addition, the reflection coefficient experiences a minimum value at frequency of 1.056 GHz. These two minimum values are functions of the permittivity of the sample under test. When the relative permittivity of the sample under test is 3, the minimum transmission frequency shifts to a frequency of 1.092 GHz, and the minimum reflection frequency shifts to 0.948 GHz.

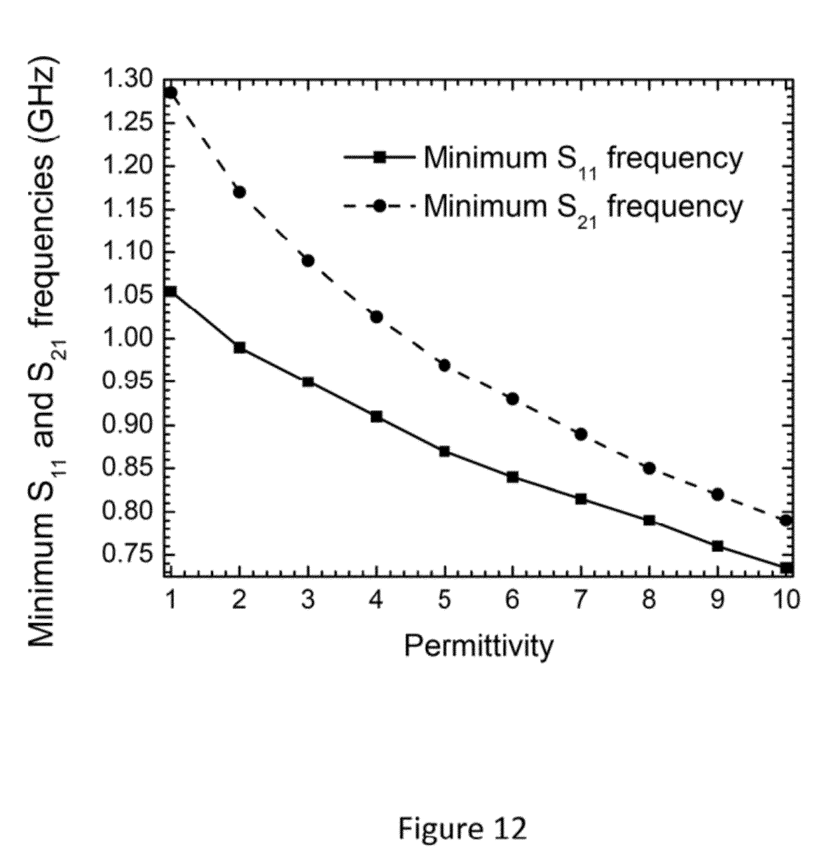

FIG. 12 shows the minimum transmission coefficient and minimum reflection coefficient as a function of the permittivity of the sample under test. Minimum transmission frequency shifts 38.5% and minimum reflection frequency shifts 30.3% when the permittivity of the sample under test changes from 1 to 10.

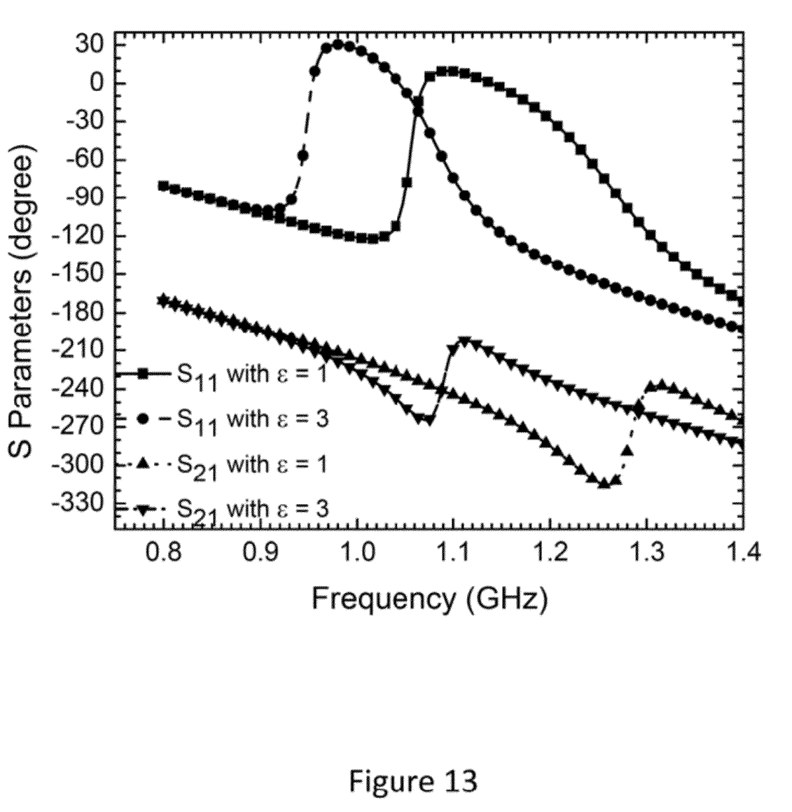

The sensor offers higher precision for permittivity measurements within a narrow permittivity range when the phase of the reflection coefficient is monitored. FIG. 13 shows that at minimum transmission coefficient and minimum reflection coefficient frequencies, the phase of the reflection and transmission coefficients experience a significant jump. Therefore at these frequencies, phases of the reflection and transmission coefficients are very sensitive to the permittivity of the sample material.

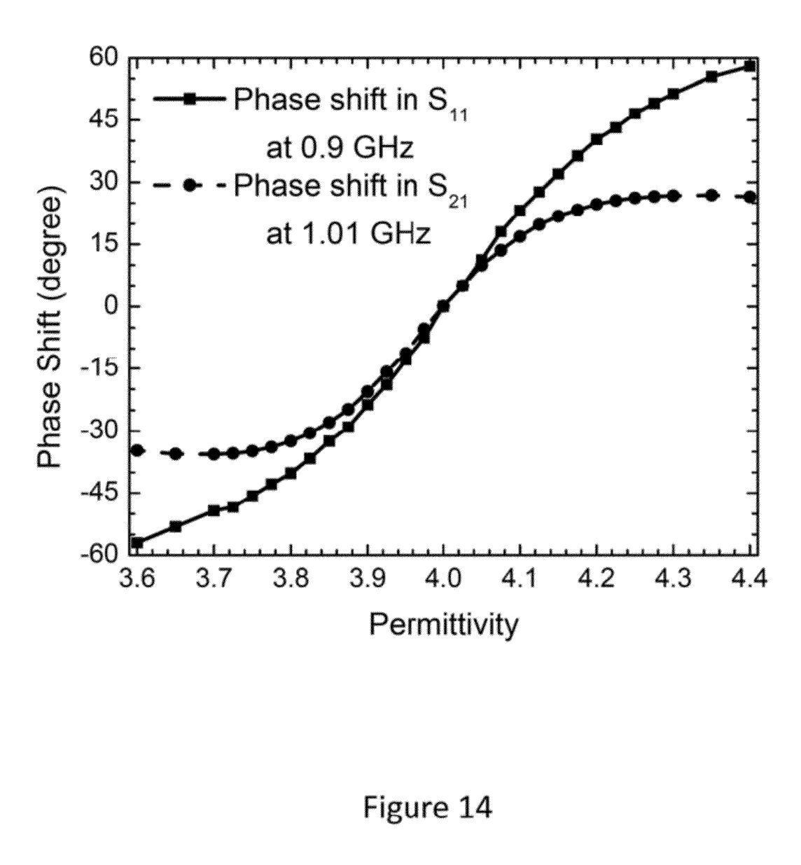

FIG. 14 shows the phase shifts in reflection and transmission coefficients as a function of the sample permittivity. The center relative permittivity is selected to be 4, around the permittivity of an FR-4 laminate. The operation frequency for the phase of the reflection coefficient is fixed to the minimum reflection frequency when the sample under test has a relative permittivity of 4. Similarly the operation frequency for the phase of the transmission coefficient is fixed to the minimum transmission frequency when the sample tinder test has a relative permittivity of 4.

Having thus described the invention, what is claimed is:

1. A method to design near-field probes employing single or multiple metamaterial unit cells.

2. A design of near-field probes employing a single metamaterial unit cell or multiple metamaterial unit cells.

3. The method of claim 1 wherein metamaterial means composite material that displays properties beyond those found in naturally occurring materials.

4. The method of claim 1 wherein near-field probes include electromagnetic devices that detect changes in material composition, or changes in material shape and location.

5. The method of claim 1 wherein near-field probes include electromagnetic devices that detect changes in the electrical and magnetic properties of material.

6. The method of claim 1 wherein the metamaterial is μ-negative, ∈-negative, or μ-negative and ∈-negative simultaneously.

7. The method of claim 1 wherein the metamaterial is made of electrically-small resonators or metamaterial unit cells or metamaterial particles such as split-ring resonators or any other resonating structure sufficient to generate net effective negative permittivity or permeability.

8. The method of claim 1 wherein the metamaterial is made of electrically-small resonators or metamaterial unit cells or metamaterial particles such as split-ring resonators or any other resonating structure sufficient to generate enhanced net permittivity or enhanced net permeability.

9. The method of claim 1 wherein the unit cell is the building block of a μ-negative metamaterial.

10. The method of claim 1 wherein the unit cell is the building block of a ∈-negative metamaterial.

11. The method of claim 1 wherein the unit cell is the building block of a metamaterial with μ-negative and ∈-negative simultaneously.

12. The method of claim 1 wherein the metamaterial unit cell is a split-ring resonator.

13. The method of claim 1 wherein the metamaterial unit cell is a complementary split-ring resonator

14. The method of claim 1 wherein the metamaterial unit cell is a spiral or split spiral.

15. The method of claim 1 wherein the metamaterial unit cell is a fractal Hilbert curve

16. The method of claim 1 wherein the near-field probe is an electromagnetic transmitter operating based on the principle of evanescent waves and the change in the magnetic and electric energy within the medium surrounding the probe.

17. The method of claim 1 wherein the near-field probe comprising the metamaterial unit cell is excited (energized) by a microstrip line, strip line, coaxial line, or other means by which a signal can be transmitted to the metamaterial unit cell in order to create resonance in the unit cell.
